(19) United States
(12) Patent Application Publication
(10) Pub. No.: US 2014/0311543 A1
(43) Pub. Date: Oct. 23, 2014

(54) THERMOELECTRIC CONVERSION GENERATING DEVICE

(71) Applicants: HITACHI CHEMICAL COMPANY, LTD., Tokyo (JP); HONDA MOTOR CO., LTD., Tokyo (JP)

(72) Inventors: Takahiro JINUSHI, Matsudo-shi (JP); Masanao TOMINAGA, Matsudo-shi (JP); Zenzo ISHIJIMA, Matsudo-shi (JP); Masayoshi MORI, Haga-shi (JP); Takeshi YAMAGAMI, Saitama-shi (JP); Hiroshi MATSUDA, Utsunomiya-shi (JP); Shiyouhei YAMASHITA, Shioya-gun (JP)

(73) Assignees: HONDA MOTOR CO., LTD., Tokyo (JP); HITACHI CHEMICAL COMPANY, LTD., Tokyo (JP)

(21) Appl. No.: 14/202,673

(22) Filed: Mar. 10, 2014

(30) Foreign Application Priority Data
Apr. 17, 2013 (JP) 2013-086541

(51) Int. Cl. H01L 35/32

(52) U.S. Cl. CPC H01L 35/32
USPC 136/205

(57) ABSTRACT

To produce a temperature difference in the thermoelectric conversion module, a tabular member of the cooling side arranged side of the thermoelectric conversion module is fitted in a uniform pressed condition on the thermoelectric conversion module. In the airtight container in which the flow tube penetrates the housing and the thermoelectric conversion module is arranged in the reduced pressure space between the housing and the flow tube, a tabular member of the cooling side of the housing corresponding to the thermoelectric conversion module is formed by the thin plate that is flexible, and the thermoelectric conversion module is sandwiched between the thin plate and the flow tube. The thin plate contacts the thermoelectric conversion module in a pressed condition by reducing pressure in the reduced pressure space, and the thin plate deforms by following the shape of the thermoelectric conversion module and fits due to its flexibility.

### TECHNICAL FIELD

The present invention relates to a thermoelectric conversion generating device in which thermal energy is converted to electrical energy by imparting a temperature difference in a thermoelectric conversion module.

### BACKGROUND ART

An electrical power generating technique is known in which thermal energy is converted to electrical energy by using a thermoelectric conversion element. The thermoelectric conversion element is an element using the Seebeck effect, in which a temperature difference is produced between separated parts, and a difference in voltages is generated between the high temperature part and the low temperature part. The amount of power generated increases as the temperature difference increases. Such a thermoelectric conversion element is used in a construction of a so-called “thermoelectric conversion element module”, in which multiple elements are joined. A thermoelectric conversion generating device is constructed in which the thermoelectric conversion module is arranged between a tabular member of a heating side and a tabular member of a cooling side, and the tabular member of the heating side is heated and the tabular member of the cooling side is cooled so as to produce a temperature difference in the thermoelectric conversion module, thereby producing electricity from the thermoelectric conversion module (See Japanese Unexamined Patent Application Publication No. 2009-088408).

In a power generating device of this kind, it is known that the amount of power generated increases as the temperature difference applied to the thermoelectric conversion module increases, as mentioned above, thereby improving power generating performance. As one method to increase the temperature difference of a thermoelectric conversion module, a method is effective in which tabular members of the heating side and the cooling side arranged on both sides of the thermoelectric conversion module are contacted tightly and uniformly on the thermoelectric conversion module so as to increase thermal conductivity via these tabular members.

For example, as disclosed in the above publication No. 2009-088408, it is possible that each tabular member is tightly contacted on the thermoelectric conversion module in a pressed condition using a fastening member such as a tie rod or a nut. However, in a case in which such members are used, it may be difficult to press the tabular member on the thermoelectric conversion module with a uniform pressure, and a structure of the device may be complicated and cost may increase. In addition, there may be a case in which freedom of layout or design is limited, and furthermore, it may be disadvantageous if a device is required to be of reduced weight.

The present invention was made in view of the above circumstances, and a primary object of the invention is to provide a thermoelectric conversion generating device in which a fitting property of the tabular member of cooling side on one side of the thermoelectric conversion module, in order to apply a temperature difference to the thermoelectric conversion module, can be improved without complicating the device and increasing cost, and in which freedom in planning or design can be improved and weight can be reduced.

### SUMMARY OF THE INVENTION

A thermoelectric conversion generating device of the present invention has an airtight container in which a tabular member of heating side and a tabular member of cooling side are arranged facing each other and in which pressure inside thereof is reduced, and a thermoelectric conversion module contained in the airtight container in a condition in which the module is arranged between the tabular member of the heating side and the tabular member of the cooling side, in which the thermoelectric conversion module generates electricity by applying a temperature difference to the thermoelectric conversion module by heating the tabular member of heating side and cooling the tabular member of cooling side at the same time, the tabular member of the cooling side consists of a flexible tabular member having flexibility, and the flexible tabular member contacts the thermoelectric conversion module directly or via a buffer material in a condition that the flexible tabular member is pressed by a pressure difference between the inside and the outside of the airtight container that occurs by a condition of reduced pressure in the airtight container. The present invention includes the case in which the buffer material is arranged between the flexible tabular member and the thermoelectric conversion module, in addition to the case in which the flexible tabular member contacts the thermoelectric conversion module directly. In this way, in the present invention, this case in which the buffer material is arranged between the flexible tabular member and the thermoelectric conversion module is expressed by “the flexible tabular member contacts the thermoelectric conversion module via a buffer material”.

In the present invention, the flexible tabular member of the cooling side contacts the thermoelectric conversion module side in a pressed condition by reducing pressure inside of the airtight container. The flexible tabular member entirely contacts a surface of the thermoelectric conversion module facing to the member by being deformed to follow the facing surface, and a condition can be obtained in which they are tightly fitted in a uniformly pressed condition. By using the flexible tabular member as a tabular member of the cooling side which partially forms the airtight container and reducing pressure inside the airtight container without using a fastening member such as tie rod or nut, the fitting property of the tabular member on the thermoelectric conversion module can be improved. Furthermore, since a fastening member such as bolt or nut is not used, freedom in planning or designing can be improved, and the weight can be reduced. Furthermore, even in a case in which a surface of thermoelectric conversion module contacting the flexible tabular member is uneven or rough, the flexible tabular member tightly fits to the surface by being deformed following the shape of the surface. Therefore, it is not necessary to improve assembling accuracy and size accuracy in order to uniformly contact the tabular member and the thermoelectric conversion module, and thus, productivity can be improved and the cost can be reduced.

The present invention includes an aspect in which a deformation part is arranged around the thermoelectric conversion module in the flexible tabular member, which deforms by pressure difference. In this aspect, by the deformation of the deformation part, a portion of the flexible tabular member facing the thermoelectric conversion module, which corresponds to an inside portion of the deformation part, may be easily deformed to the thermoelectric conversion module side, and thus the fitting property to the thermoelectric conversion module is further improved.

Furthermore, the present invention includes an aspect in which a heat exchanging means for improving cooling is arranged on the tabular member of the cooling side in a condition in which flexibility of the tabular member of the cooling side can be maintained. In this aspect, heat in the tabular member of the cooling side is conducted to the heat exchanging means, and the heat thereof is radiated, and cooling efficiency of the thermoelectric conversion module by the tabular member of the cooling side is improved. Since the heat exchanging means can maintain flexibility of the tabular member of the cooling side, improvement of fitting property of the tabular member of the cooling side to the thermoelectric conversion module, which is an action and effect of the present invention, can be maintained.

As the heat exchanging means, a heat exchanging member having flexibility or a structure in which isolated multiple heat exchanging members are arranged while being scattered and contacted to the tabular member of the cooling side consisting of flexible tabular member, can be mentioned.

Furthermore, the present invention includes an aspect in which a hollow part is formed by the tabular member of the heating side, the thermoelectric conversion module is arranged around the hollow part, the tabular member of cooling side is arranged outside of the thermoelectric conversion module, and a heating fluid is flowed through the hollow part so as to heat the tabular member of the heating side. In this aspect, by flowing the heating fluid through the hollow part, the tabular member of the heating side can be efficiently heated without scattering the heating fluid.

Furthermore, the present invention includes an aspect in which cooling fluid is supplied and the cooling fluid is contacted to the tabular member of the cooling side, and a cooling chamber in which pressure therein can be increased by the cooling fluid is arranged. In this aspect, also by inner pressure of the cooling chamber generated by supplying the cooling fluid, the tabular member of the cooling side (flexible tabular member) contacts the thermoelectric conversion module in a pressed condition. Therefore, the tabular member of cooling side can be fitted on the thermoelectric conversion module in a uniformly pressed condition.

According to the present invention, fitting property of the tabular member of the cooling side on the thermoelectric conversion module which is arranged on a side of the thermoelectric conversion module in order to produce a temperature difference in the thermoelectric conversion module, can be improved without complicating the device and increasing cost, and in addition, freedom in planning or designing can be improved and weight can be reduced.

### BRIEF DESCRIPTION OF DRAWING

FIG. 1 is an overall oblique view of the thermoelectric conversion generating device according to the First Embodiment of the present invention.

FIG. 2 is a view seen from the direction of arrow II in FIG. 1.

FIG. 3 is a cross sectional view at in FIG. 2.

FIG. 4 is a cross sectional view at Iv-Iv in FIG. 2.

FIG. 5 is an oblique view showing a structure of a housing of the airtight container of the generating device, FIG. 5A is a disassembled condition, and FIG. 5B is an assembled condition.

FIG. 6 is a front view showing the thermoelectric conversion module of the generating device.

FIGS. 7A and 7B are a plan view showing an example of a heat exchanging member arranged on a thin plate of the housing in the generating device.

FIG. 8 is an overall oblique view of the thermoelectric conversion generating device according to the Second Embodiment of the present invention.

FIG. 9 is an oblique view showing a condition in which an outer cover and sealing cover are detached in the thermoelectric conversion generating device of the Second Embodiment.

FIG. 10 is a side view of the thermoelectric conversion generating device of the Second Embodiment.

FIG. 11 is a cross sectional view at XI-XI in FIG. 10.

FIG. 12 is a front view of the thermoelectric conversion generating device of the Second Embodiment.

FIG. 13 is a cross sectional view at XIII-XIII in FIG. 12.

FIG. 14A is a front view and FIG. 14B is a side view of a generating unit constructing the thermoelectric conversion generating device of the Second Embodiment.

FIG. 15 is a cross sectional view conceptually showing a structure of the airtight container and an end part cooling part in the generating unit of thermoelectric conversion generating device of the Second Embodiment, FIG. 15A shows a condition before joining a cooling case, and FIG. 15B shows a condition in which the cooling case is joined and an inner rigid part of a movable plate part is pressed to the thermoelectric conversion module by an elastic plate.

FIG. 16 is a cross sectional view conceptually showing a structure of the airtight container and an intermediate cooling part of the generating unit of the Second Embodiment, and showing a condition in which the inner rigid part is pressed to the thermoelectric conversion module by an elastic plate which is sandwiched between inner rigid parts of the movable plate part.

FIG. 17 is a cross sectional view showing a variation of the elastic plate of the Second Embodiment, FIG. 17A shows a condition before the cooling case is joined, and FIG. 17B shows a condition in which the cooling case is joined and an inner rigid part of a movable plate part is pressed to the thermoelectric conversion module by an elastic plate.

FIG. 18 is a view showing another variation of the elastic plate of the Second Embodiment, FIG. 18A shows a condition before the cooling case is joined, and FIG. 18B shows a condition in which the cooling case is joined and an inner rigid part of a movable plate part is pressed to the thermoelectric conversion module by an elastic plate.

FIG. 19 is a cross sectional view conceptually showing a vicinity of an end part cooling part in a generating unit of the thermoelectric conversion generating device of the Third Embodiment of the present invention, FIG. 19A shows a condition before reducing pressure inside of the airtight container, and FIG. 19B shows a condition of reducing pressure inside of the airtight container.

FIG. 20 is a cross sectional view conceptually showing a vicinity of the intermediate cooling part in the generating unit of the Third Embodiment, and shows a condition of reducing pressure inside of the airtight container.

FIG. 21A is a front view and FIG. 21B is a side view of a generating unit constructing the thermoelectric conversion generating device of the Fourth Embodiment of the present invention.

FIG. 22 is a cross sectional view conceptually showing the structure of a main part of the airtight container of a generating unit of the Fourth Embodiment, FIG. 22A shows a condition before joining a movable plate part of the housing, and FIG. 22B shows a condition in which the movable plate part is joined and an inner rigid part is fitted on the thermoelectric conversion module in a pressed condition.

FIG. 23 is a cross sectional view showing a variation of the Fourth Embodiment, that is, the variation in which a spring plate constructing elastic part of the movable plate part is circular, FIG. 23A shows a condition before the movable plate part is joined, and FIG. 23B shows a condition in which the movable plate part is joined.

### EXPLANATION OF REFERENCE NUMERALS

11: Thermoelectric conversion generating device, 12: Airtight container, 122: Thin plate of housing (tabular member of cooling side, flexible tabular member), 1221: Deformation part, 1251: Main plate part of flow tube (tabular member of heating side), 14: Thermoelectric conversion module, 15: Buffer material, 16: Heat exchanging means, 161, 162: Fin (heat exchanging member), 351: Hollow part, 53a, 53b: Cooling jacket (cooling chamber), W: Cooling water (fluid for cooling), H: Heating fluid.

### BEST MODE FOR CARRYING OUT THE INVENTION

Next, the First to Fourth Embodiments of the present invention are explained with reference to the drawings

### [1] First Embodiment

### [1-1] Structure of Thermoelectric Conversion Generating Device

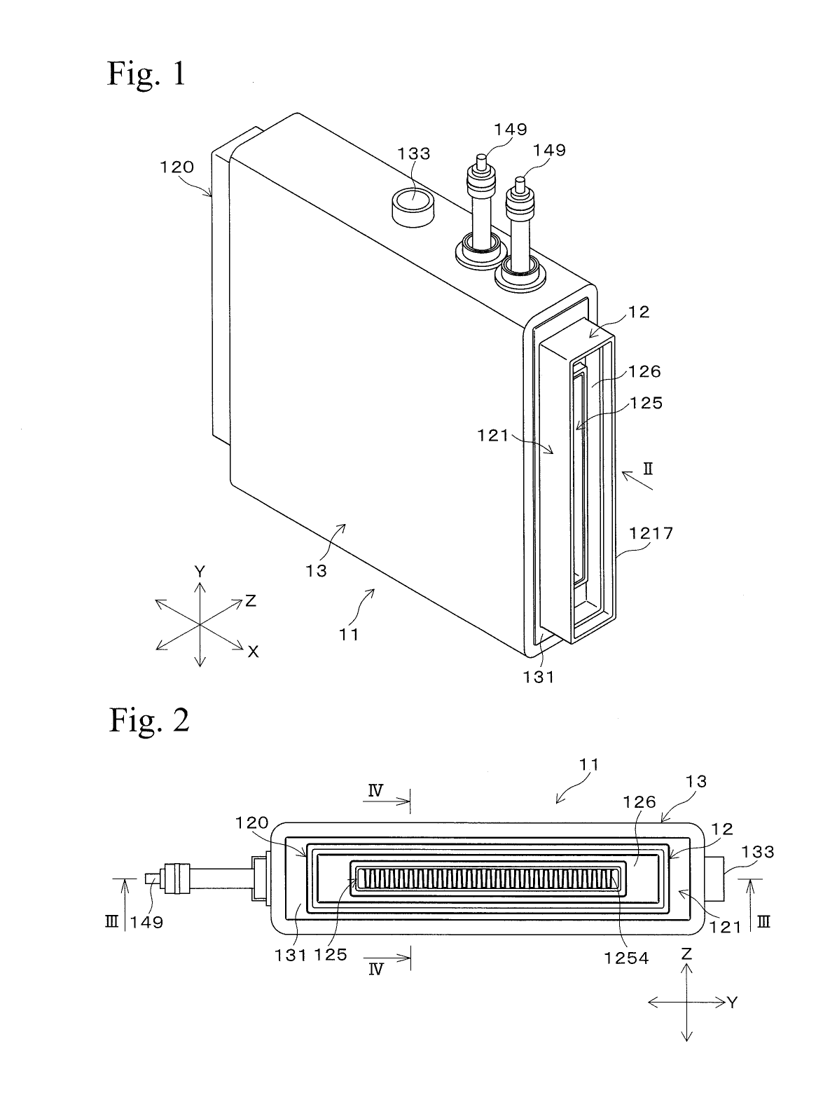

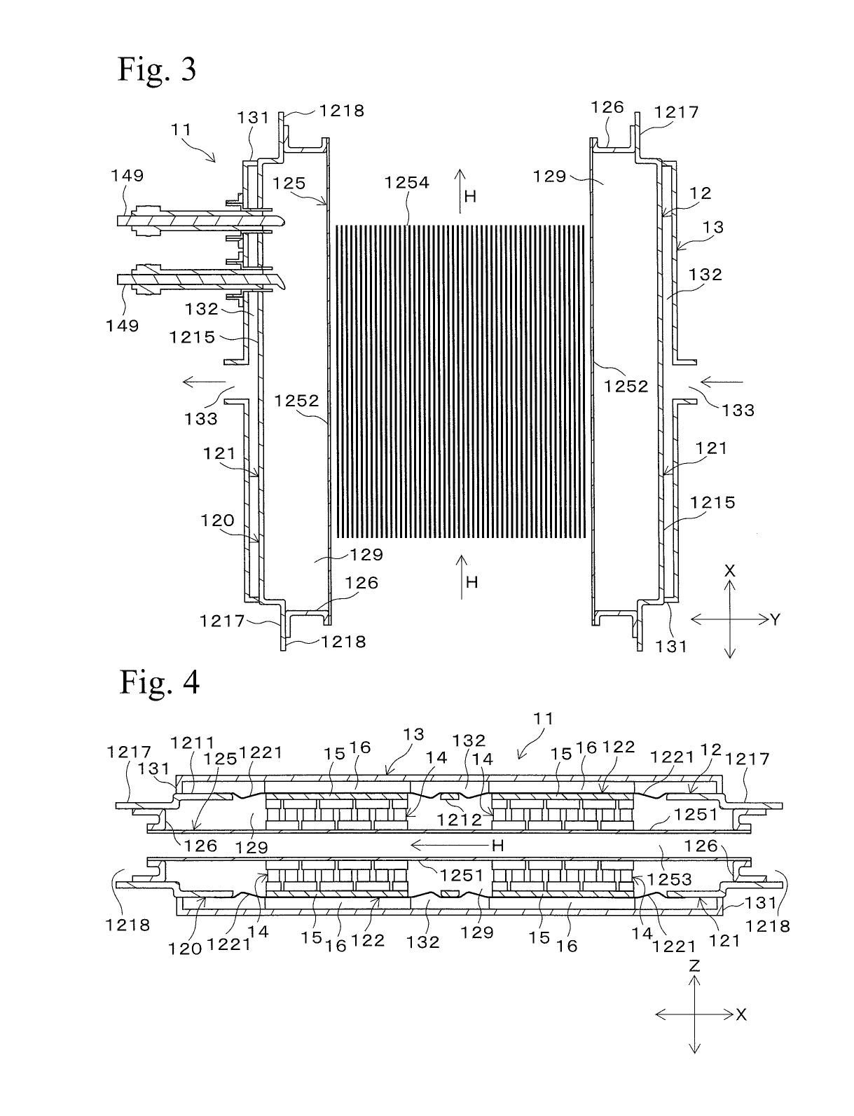

FIGS. 1 to 4 show the thermoelectric conversion generating device (hereinafter referred to as a “generating device”) 11 of the First Embodiment, FIG. 1 is an overall oblique view, FIG. 2 is a view seen from the direction of arrow II in FIG. 1, and FIGS. 3 and 4 are a cross sectional view at and Iv-Iv, respectively, in FIG. 2. This generating device 11 is formed in a cuboid shape in which the entirety is flat (the X direction in FIGS. 1, 3 and 4 is the longitudinal direction), and includes a water cooling jacket 13 and an airtight container 12 contained in the water cooling jacket 13.

The airtight container 12 has a double-tube structure in which a flow tube 125 having a flat tube shape is contained in central part of a housing 120 having a flat tube shape. A space between the housing 120 and the flow tube 125 is a reduced pressure space 129, and each of the openings of both ends in the X direction of the reduced pressure space 129 is sealed airtight by a sealing cover 126. The water cooling jacket 13 is formed in a flat tube shape almost conforming to the outer shape of the airtight container 12. Both end parts of the opening side of the airtight container 12 contained in the jacket project from both end openings of the water cooling jacket 13.

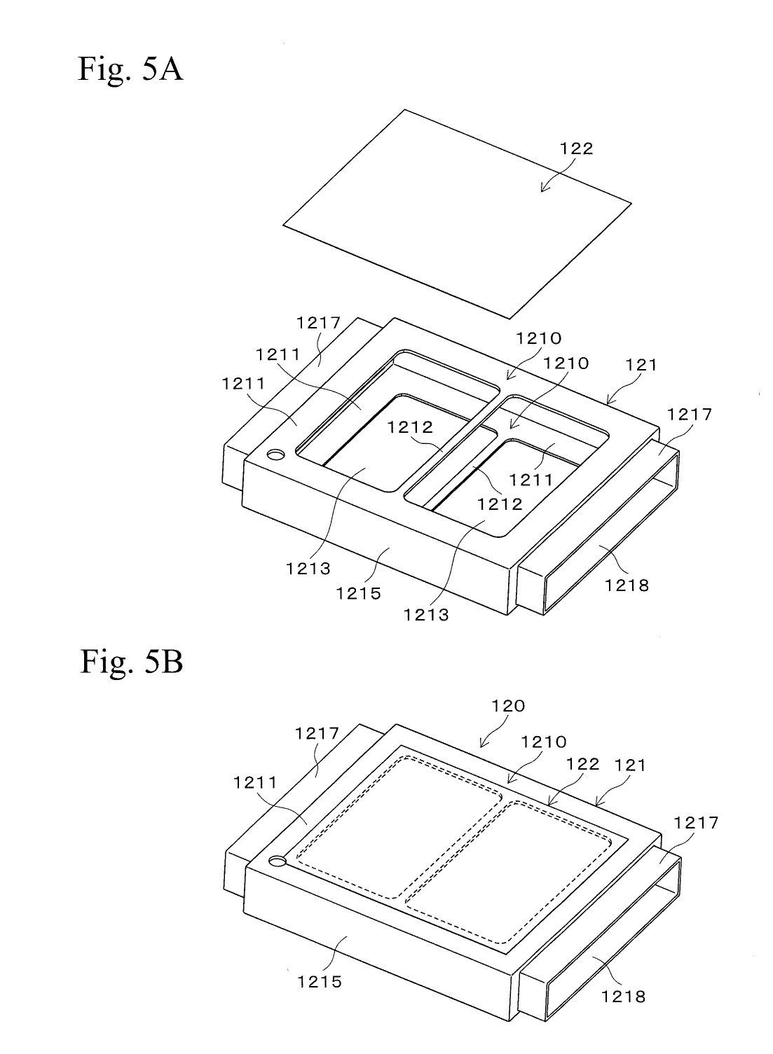

As shown in FIG. 5, the housing 120 is constructed by a rigid part 121 in which a pair of frame plates 1210, the plates facing each other in parallel via a certain gap in a vertical direction (Z direction); the frame plate 1210 consists of a rectangular outer frame plate part 1211 and an inner frame plate part 1212 dividing inside of the outer frame plate part 1211 into two holes 1213 mutually separated along longitudinal direction (X direction); edges of the outer frame plate parts 1211 along the longitudinal direction are connected by side plate parts 1215; and opening tube parts 1217 forming openings 1218 at both end parts along the longitudinal direction, and a rectangular thin plate (tabular member of the cooling side, flexible tabular member) 122 which seals the two holes 1213 of the lower and upper frame plates 1210 of the rigid part 121. The thin plate 122 is flexible and is formed in a size that can cover the two holes 1213 by a tabular material elastically deformable in upper and lower directions. The thin plate 122 is joined to the circumference of the holes 1213 (outer surface of the outer frame plate part 1211 and the inner frame plate part 1212) from the outside of the rigid part 121, by a joining means such as brazing. As a material of the thin plate 122, a metallic plate having heat resistance and oxidation resistance, such as stainless steel, such as SUS444 or aluminum, is desirable, having a thickness of about 0.1 mm, for example.

The flow tube 125 contained inside of the housing 120 is formed so that edges along the longitudinal direction of a pair of upper and lower rectangular main plate parts (tabular member of the heating side) 1251 parallel to the upper and lower frame plate 1210 of the housing 120 are connected by side plate parts 1252 parallel to the side plate parts 1215 of the housing 120. The outer surface of both end openings thereof is joined to the inner surface of the opening tube part 1217 of the rigid part 121 of the housing 120, via the sealing cover 126 having a U-shaped cross section projecting to the inside and having an oval shape overall.

The inside of the flow tube 125 forms a heating fluid pathway 1253 through which the heating fluid H (see FIGS. 3 and 4) flows from one opening to the other opening. In this heating fluid pathway 1253, fins 1254 through which heat of the heating fluid H is conducted to the flow tube 125, are arranged. As the fin 1254, for example, a corrugated plate formed by bending a tabular material can be used. The fin 1254 and the sealing cover 126 are joined to the rigid part 121 and the flow tube 125, respectively, by a joining means such as brazing. It should be noted that the fin 1254 is arranged only if necessary, and there may be a case in which a hollow space is formed in the heating fluid pathway 1253 without using the fin 1254.

A material similar to the thin plate 122 is used as a material of the rigid part 121 of the housing 120 constructing the airtight container 12, the flow tube 125, and the sealing cover 126. In such the airtight container 12, the thermoelectric conversion module 14 is arranged at each of the two spaces between the thin plate 122 of the housing 120 and the main plate part 1251 of the flow tube 125.

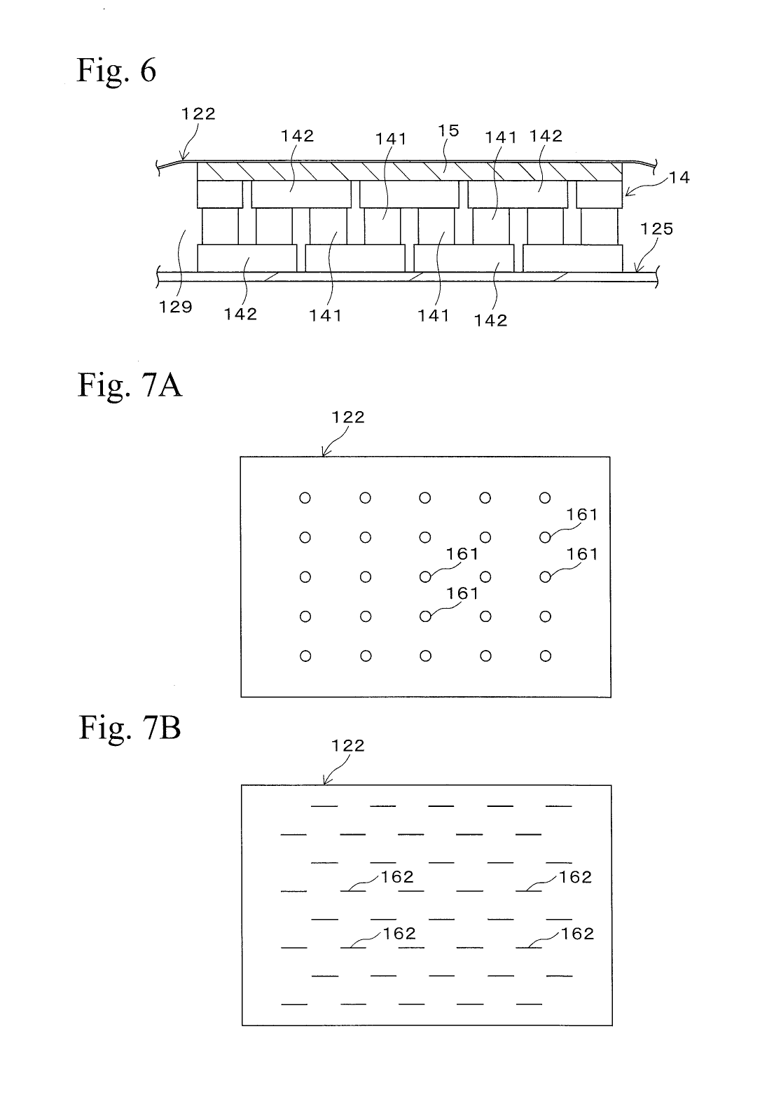

As shown in FIG. 6, the thermoelectric conversion module 14 is constructed in which one of the side surfaces and the other of the side surfaces of the multiple thermoelectric conversion elements 141 arranged planar are connected in series and in a zigzag by electrodes 142 made of rectangular metallic plate such as copper plate, and the electrodes 142 of one surface side are joined to the inner surface of the main plate part 1251 of the flow tube 125 by a joining means such as brazing. Furthermore, the electrodes 142 of the other surface side of the thermoelectric conversion module 14 face to the inner surface of the thin plate 122 of the housing 120, and buffer material 15 is held while sandwiched between the thin plate 122 and electrodes 142. That is, the thin plate 122 contacts the thermoelectric conversion module 14 via the buffer material 15.

A sheet shape having flexibility is desirable as the buffer material 15, for example, a thin carbon sheet or the like is used. It should be noted that although the buffer material 15 is arranged between the thin plate 122 and the thermoelectric conversion module 14 in this Embodiment, the buffer material 15 is used only if necessary, and the thin plate 122 can directly contact the thermoelectric conversion module 14.

As a thermoelectric conversion element 141 constructing the thermoelectric conversion module 14, a kind having high heatproof temperature is used, for example, a silicon-germanium type, magnesium-silicon type, manganese-silicon type, iron silicide type or the like is desirably used. The reduced pressure space 129 in the airtight container 12 in which the thermoelectric module 14 is contained is sealed in airtight condition by the housing 120 consisting of the rigid part 121 and the thin plate 122, the flow tube 125, and the sealing cover 126.

As shown in FIG. 4 (description of the fin 1254 is omitted in FIG. 4), a part of the thin plate 122 corresponding to surrounding area of the thermoelectric conversion module 14 forms a deformation part 1221 having a cross sectional shape of a triangle protruding to the flow tube 125 side, along the entire circumference. This deformation part 1221 is formed between inner circumference of the hole 1213 and the thermoelectric conversion module 14.

The airtight container 12 is contained in the water cooling jacket 13. As described above, the water cooling jacket 13 is formed in a flat tube shape almost conforming to the outer shape of the airtight container 12, and the opening tube part 1217 at both ends of the airtight container 12 protrude from the opening of both ends of the water cooling jacket 13. Sealing frame parts 131, which are formed at both opening ends of the water cooling jacket 13 and are bent to the inside, are joined to an outer surface of the outer frame plate part 1211 of the rigid part 121 of the airtight container 12 by a means such as brazing in an airtight condition. A space inside of the water cooling jacket 13, that is, a space which is formed between the rigid part 121 and the water cooling jacket 13, functions as a cooling space 132 for cooling the thin plate 122 by means of supplying cooling water therein. Inlet and outlet 133 for the cooling water are arranged at the central parts of the water cooling jacket 13 corresponding to each side plate part 1215 of the housing.

In total, four thermoelectric conversion modules 14 are contained in the airtight container 12, and these thermoelectric conversion modules are connected in series. Electricity is obtained at the outside from two lead wires 149 that are “+” and “−”, as shown in FIGS. 1 and 2. The lead wires 149 are drawn to the outside penetrating the side plate part 1215 of the airtight container 12 and the water cooling jacket 13, and the penetrating hole of the lead wire on the side plate part 1215 and the water cooling jacket 13 is treated so that the hole is sealed airtight.

At a part in the cooling space 132 corresponding to the thermoelectric conversion module 14, the heat exchanging means 16 is joined to the thin plate 122. The heat exchanging means 16 promotes cooling by radiating heat from the thin plate 122 by contacting to the cooling water supplied and flowed in the cooling space 132, and is arranged in a condition that flexibility of the thin plate 122 is not interfered with, that is, in a condition in which flexibility of the thin plate 122 is sustainable.

As the heat exchanging means 16 that can be sustain flexibility of the thin plate 122, a means consisting of a heat exchanging member of a fin or the like having flexibility can be mentioned. Furthermore, even a heat exchanging member of a hard fin or the like can be used as long as the isolated multiple heat exchanging members are separately arranged and contact the thin plate 122 so as to sustain flexibility of the thin plate 122.

As such a heat exchanging member, as shown in FIG. 7A, a structure can be mentioned in which multiple needle shaped fins 161 are evenly arranged on the thin plate 122 and joined while standing. In addition, as shown in FIG. 7B, a structure can also be mentioned, in which short thin plate fins 162 are arranged offset and in a houndstooth arrangement on the thin plate 122 and joined while standing.

The airtight container 12 is sealed airtight by drawing out the air of the reduced pressure space 129 from an outlet for pressure reducing and sealing which is formed at a certain location and is not drawn in the figure so as to reach a predetermined pressure (about 1 to 100 Pa for example) in the reduced pressure space 129, and by welding the outlet for pressure reducing and sealing. In this way, pressure difference occurs in the reduced pressure space 129 in the airtight container 12, that is, the pressure becomes lower than the outer atmosphere, and the thin plate 122 of the housing 120 receives a force pressed at the thermoelectric conversion module 14 side by this pressure difference.

### [1-2] Operation of Generating Device

In the generating device 11 comprising the above structure, the cooling water is introduced in the cooling space 132 from one inlet and outlet 133 of the water cooling jacket 13, and the cooling water is drawn from the other inlet and outlet 133, so that the cooling water flows in the cooling space 132 in a condition that the cooling water is filled in the cooling space 132, in order to cool the thin plate 122 of the airtight container 12. In addition, the heating fluid H at high temperature flows through the heating fluid pathway 1253 in the flow tube 125, from one opening to the other opening to heat the flow tube 125. Cooling of the thin plate 122 is promoted by the heat exchanging means 16, which is cooled by the cooling water. Temperature of the thin plate 122 that is cooled is conducted to an outer surface side of the thermoelectric conversion module 14, and the outer surface side of the thermoelectric conversion module 14 is cooled. On the other hand, temperature of the main plate part 1251 of the flow tube 125 that is heated is conducted to an inner surface side of the thermoelectric conversion module 14, and the inner surface side of the thermoelectric conversion module 14 is heated.

In this Embodiment, the thin plate 122 of the housing 120 functions as the tabular member of the cooling side, and the main plate part 1251 of the flow tube 125 functions as the tabular member of the heating side. As described above, by producing a temperature difference between the outer surface side and the inner surface side of the thermoelectric conversion module 14, the thermoelectric conversion module 14 generates electricity, and the electricity can be obtained from the lead wires 149.

For example, exhaust heat gas generated by a factory or garbage incinerator, or exhaust gas of vehicles, may be used as the heating fluid H in the generating device 11 of this Embodiment.

### [1-3] Action and Effect of First Embodiment

By the generating device 11 of the First Embodiment, by the pressure difference between reduced pressured space 129 inside of the airtight container 12 and the outside as described above, the thin plate 122 of the housing 120 is pressed to the thermoelectric conversion module 14 side. The thin plate 122 is contacted to the thermoelectric conversion module 14 side via the buffer material 15 while being pressed.

Here, since the thin plate 122 and the buffer material 15 is flexible, the thin plate 122 deforms following the shape of the surface of the electrodes 142 of the thermoelectric conversion module 14 which is a facing surface to the thin plate 122, and then entirely contacted. In this way, the thin plate 122 is fit to the thermoelectric conversion module 14 via the buffer material 15 in a uniformly pressed condition, and fitting property is improved. As a result, cooling efficiency of the electrodes 142 of the cooling side of the thermoelectric conversion module 14 is increased and temperature difference given to the thermoelectric module 14 is also increased, thereby improving power generating performance. Although the thermoelectric conversion module 14 is pressed by the thin plate 122, it is protected by the buffer material 15 arranged therebetween.

Furthermore, since the thin plate 122, which is the tabular member of the cooling side, is fitted to the thermoelectric conversion module 14 by an action of reduced pressure without using a member for fastening such as a tie rod or nut, the thin plate 122 can be fitted in uniformly pressed condition on the thermoelectric conversion module 14 without complication and high cost. Furthermore, since the member for fastening, such as a bolt and nut, is not used, freedom in planning or designing can be improved and the weight can be reduced.

Furthermore, even in a case in which the contacting surface of the electrodes 142 of the thermoelectric conversion module 14 to which the thin plate 122 is contacted via the buffer material 15 is uneven or rough, the thin plate 122 conforms to the contacting surface and is deformed and fitted thereon. Therefore, it is not necessary to improve assembling accuracy and size accuracy in order to contact the housing 120 side and the thermoelectric conversion module 14 side uniformly, and as a result, improvement in productivity and reduction in cost can be realized.

In this Embodiment, a part of the thin plate 122 corresponding to surrounding area of the thermoelectric conversion module 14 forms the deformation part 1221. By deforming the deformation part 1221 by the pressure difference, the thin plate 122 becomes easily deformed to the thermoelectric conversion module 14 side, and thus fitting property to the thermoelectric conversion module 14 is improved.

Furthermore, in the present Embodiment, the temperature of the thin plate 122 that is the tabular member of the cooling side is conducted to the heat exchanging means 16, and then the heat is radiated away, and cooling efficiency of the thermoelectric conversion module 14 by the thin plate 122 is improved. Since the heat exchanging means 16 can sustain flexibility of the thin plate 122, effect of improving fitting property of the thin plate 122 on the thermoelectric conversion module 14 can be maintained.

It should be noted that the above First Embodiment is one practical example, and the present invention is not limited to this Embodiment, and various variations are possible regarding a practical constitution as long as it includes the present invention. For example, the flexible tabular member is employed as the tabular member of the cooling side (the thin plate 122) in the First Embodiment, it is possible to employ a constitution in which a flexible tabular member is used as the main plate part 1251 of the flow tube 125 that is the tabular member of the heating side arranged the opposite side of the thermoelectric conversion module 14.

### [2] Second Embodiment

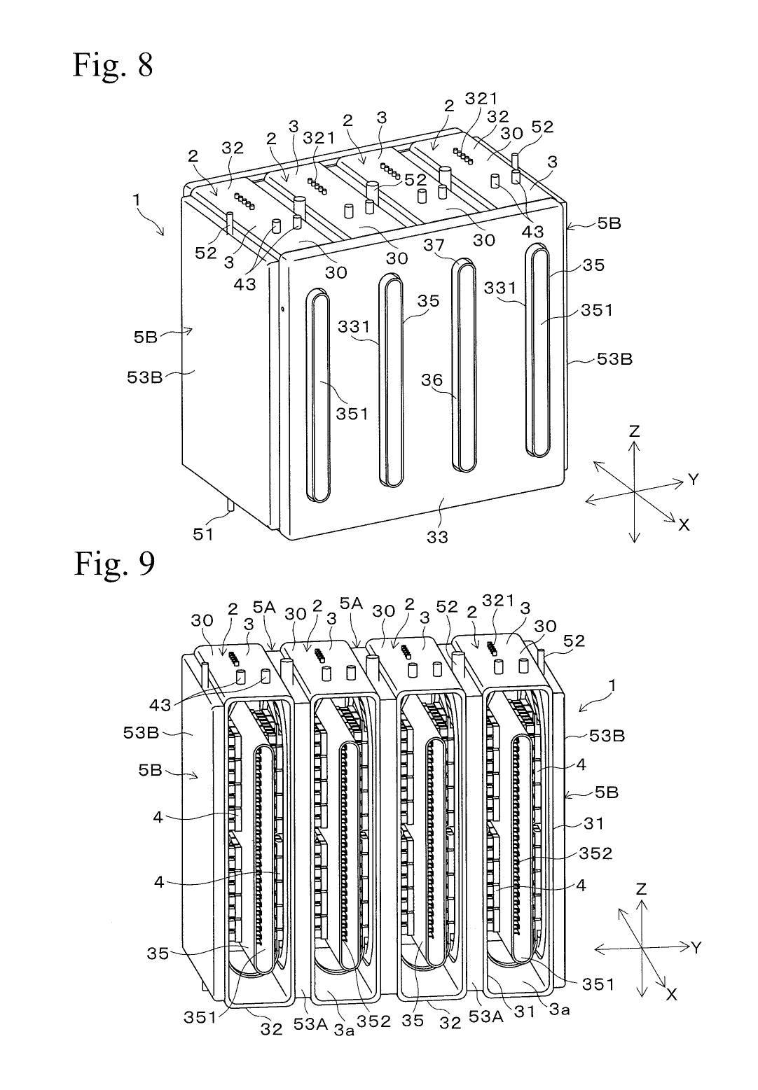

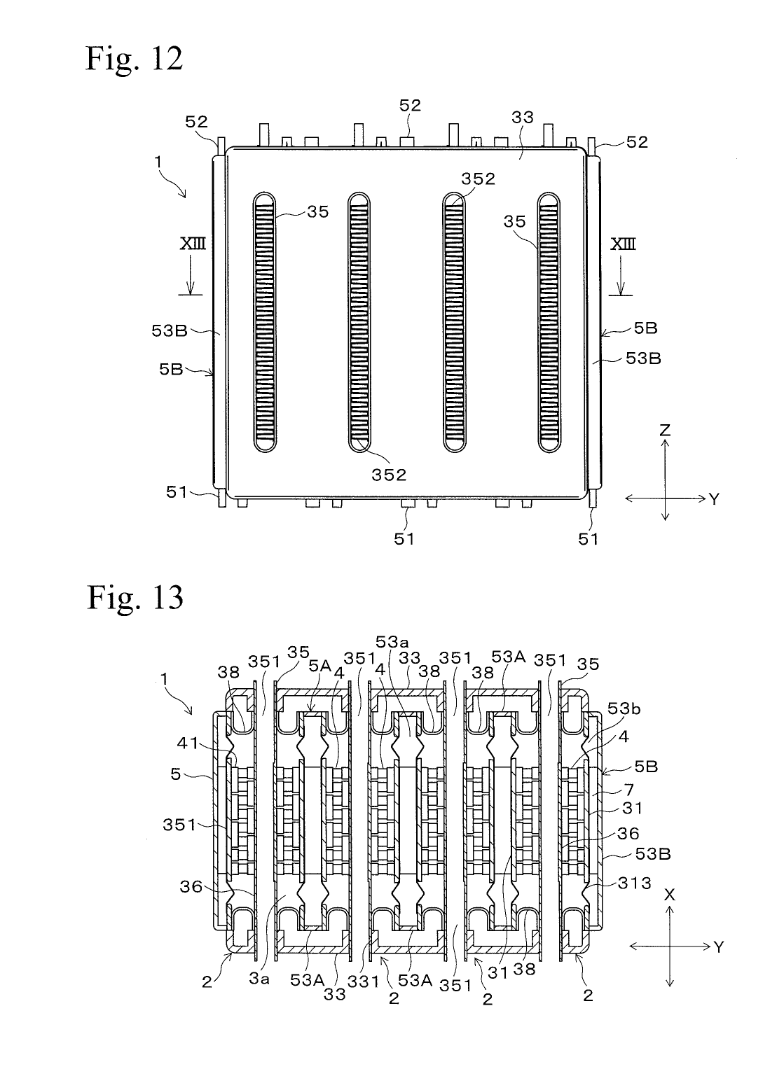

Next, the Second Embodiment of the present invention is explained with reference to the FIGS. 8 to 18.

### [2-1] Overall Structure of Thermoelectric Conversion Generating Device

FIGS. 8 to 13 show the thermoelectric conversion generating device 1 (hereinafter referred to as the “generating device”) of the Second Embodiment. This generating device 1 has a structure in which multiple generating units 2 each having an airtight container 3 are layered parallel along the Y direction with each unit sandwiching a cooling part 5A therebetween, and a cooling part 5B is also arranged at both side surfaces of the overall device 1, that is, both end parts along the Y direction. The number of generating unit 2 can be freely selected, and in this case, the structure of the generating device 1 is shown, in which four generating units 2 are layered.

The airtight container 3 is constructed by a housing 30 having approximately cuboid box shape being longer along the Z direction in a cross section (Y-Z cross section), a flow tube 35 having a flat tube shape that is longer along the Z direction in a cross section arranged at a central part in the housing 30, and sealing cover 38 (see FIG. 13) sealing openings of both ends along the X direction. Both of the housing 30 and the flow tube 35 have openings at both ends along the X direction, and inside of the flow tube 35 forms a hollow part 351 in which heating fluid mentioned below flows along the X direction.

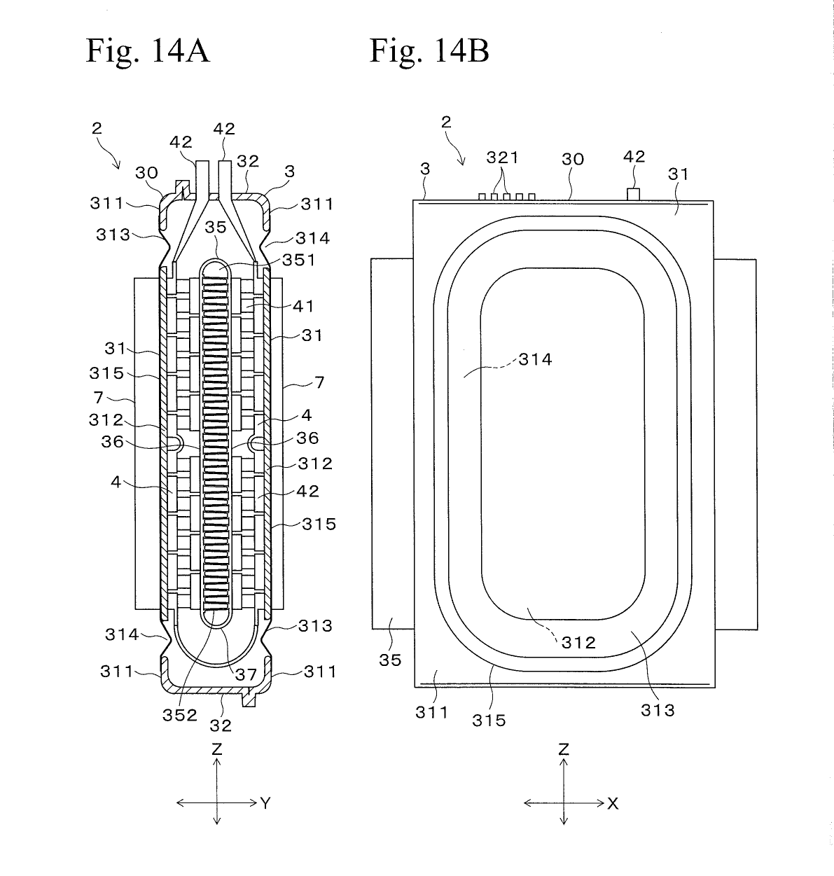

As shown in FIG. 14, the housing 30 is formed in approximately cuboid box shape by a pair of movable plate parts (tabular member of cooling side) 31 facing each other and parallel to the X-Z plane, and a pair of end plate parts 32 having a flat planar shape and connecting upper and lower edges of the movable plate parts 31. In addition, the flow tube 35 is formed in a flat tube shape by a pair of inner plate parts (tabular member of heating side) 36 facing each other and parallel to the X-Z plane, and a pair of bending parts 37 having a half-circular arc shape cross section and connecting upper and lower edges of the inner plate parts 36.

Inside of the flow tube 35, that is, in the hollow part 351 of the airtight container 3, fins 352 are arranged. The fin 352 is formed in a corrugated plate shape by bending a tabular material and is joined by a joining means such as brazing in a condition that outside of the bent parts are contacted on an inner surface of the inner plate part 36.

Inside of the airtight container 3, that is, between the inner surface of the housing 30 and the outer surface of the flow tube 35, an inner space 3a is formed having an approximately circular shape in which longitudinal cross section is longer along the Z direction. At both sides of the Y direction in the inner space 3a, the thermoelectric conversion modules 4 are arranged in each space in a condition in which the module is sandwiched between the movable plate part 31 of the housing 30 and the inner plate part 36 of the flow tube 35.

The multiple airtight containers 3 each having the inner space 3a in which the thermoelectric conversion modules 4 are arranged making pairs in the both regions of the Y direction, are layered in parallel along the Y direction in a condition that the cooling part 5A is sandwiched between the movable plate parts 31, as shown in FIGS. 11 and 13. Furthermore, the cooling part 5B is also arranged on each of the outer surfaces of the movable plate part 31 of both ends along the Y direction. Hereinafter, the cooling part 5A between the airtight containers 3 is called an “intermediate cooling part 5A”, and the cooling part 5B at the both ends of the Y direction is called an “end part cooling part 5B”.

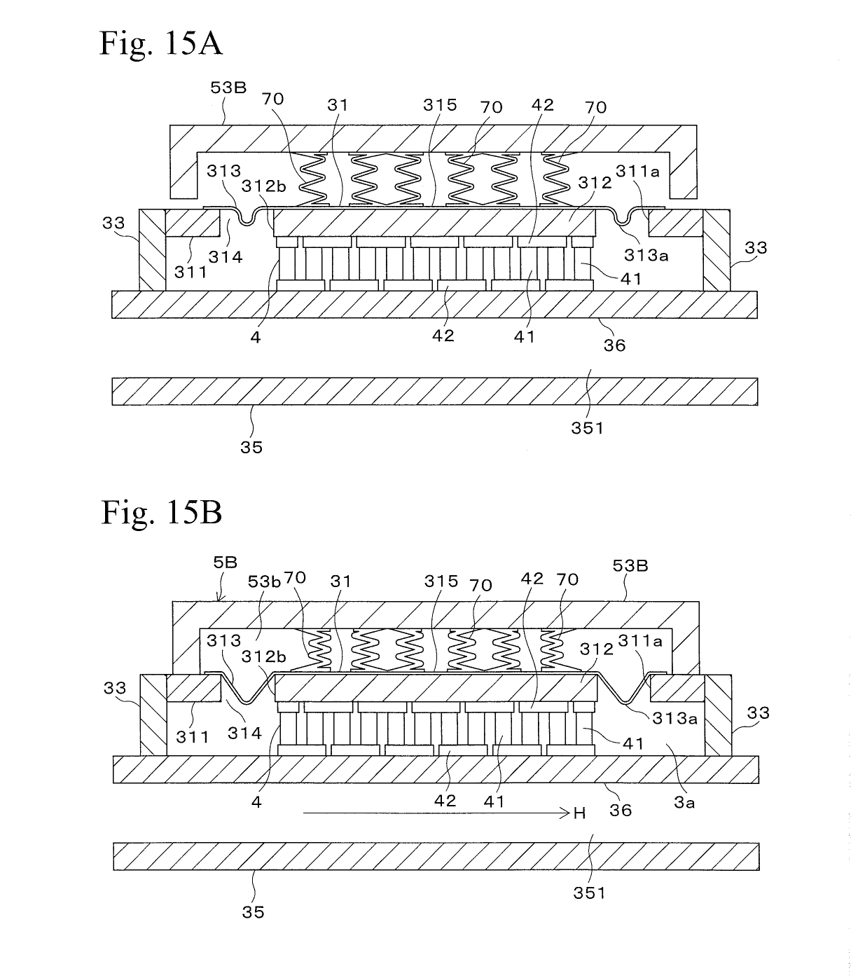

As shown in FIG. 15, the thermoelectric conversion module 4 is constructed in which of the side surfaces and the other of the side surfaces of the multiple thermoelectric conversion elements 41 arranged to be planar are connected in a zigzag by electrodes 42 made of, for example, copper, and the electrodes 42 of one surface side are joined to the inner surface of the inner plate part 36 of the flow tube 35 by a joining means such as brazing. Furthermore, the electrodes 42 of the other surface side of the thermoelectric conversion module 4 contacts the inner surface of an inner rigid part 312 explained below of the movable plate part 31 of the housing 30. That is, the thermoelectric conversion module 4 is not joined to the inner rigid part 312, and they can be relatively moved along the contacting surface thereof.

As a thermoelectric conversion element 41 constructing the thermoelectric conversion module 4, a kind having high heatproof temperature is used, for example, of the silicon-germanium type, magnesium-silicon type, manganese-silicon type, iron silicide type is desirably used. A pair of terminals 43 is connected to the thermoelectric conversion module 4 so as to obtain electricity. In this case, as shown in FIG. 14A, the terminals 43 are drawn upward in the upper part of the inner space 3a, and protrude to the outside penetrating the end plate part 32 of the upper side of the airtight container 3. The penetrating hole of the terminal 43 on the end plate part 32 is treated so that the hole is sealed airtight.

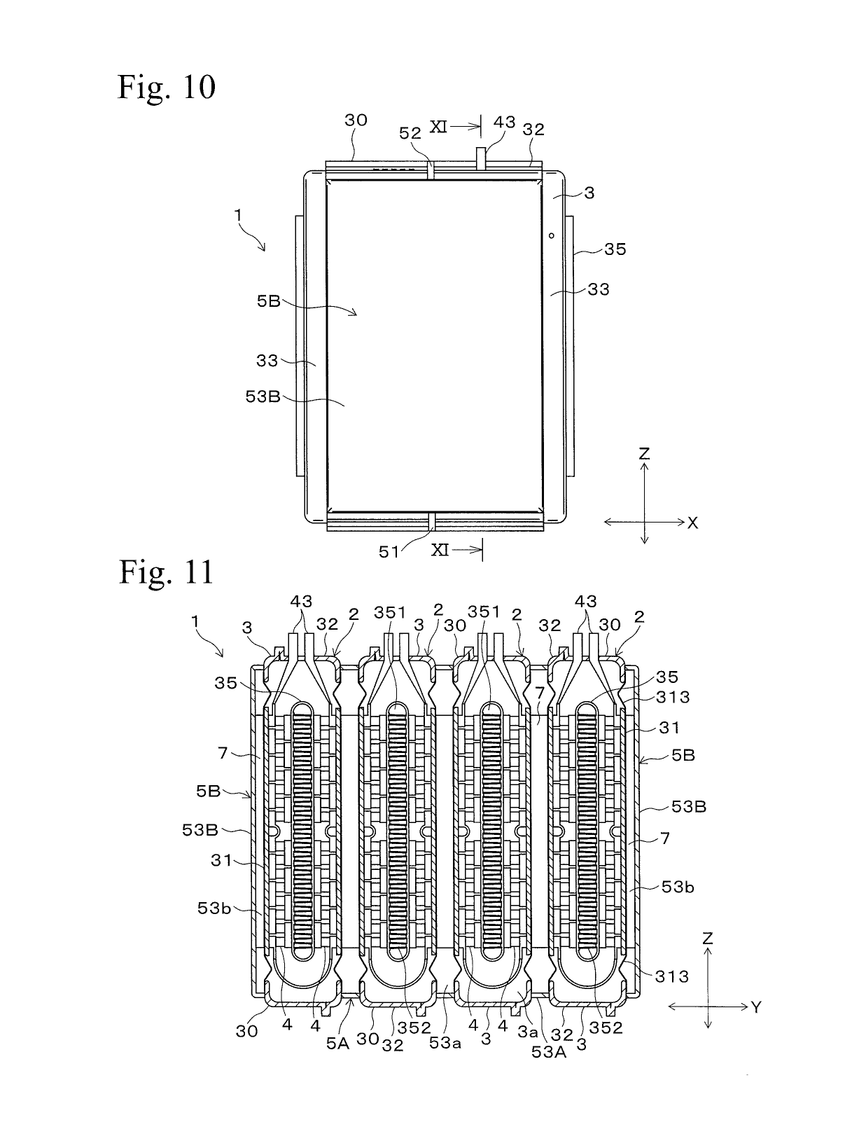

As shown in FIG. 13, an opening of the X side of the inner space 3a of the airtight container 3 is sealed by a sealing cover 38 having a U-shaped cross section projecting to the inside and having an oval shape overall. The sealing cover 38 is joined airtight to the inner surface of an outer rigid part 311 mentioned below of the movable plate part 31 and the outer surface of the end part of the X direction of the flow tube 35. The inner space 3a of the airtight container 3 is sealed airtight by the housing 30, the flow tube 35, and the sealing cover 38. As shown in FIGS. 8 and 10, outer cover 33 is joined to both end surfaces in the X direction of the housing 30 of each airtight container 3, that is, both sides in the X direction of the device 1 of the present invention is covered with this outer cover 33. The two end parts in the X direction of each flow tube 35 protrude from the each housing 30, and these protruding end parts protrude to the outside penetrating flow tube inserting hole 331 formed on the outer cover 33.

### [2-2] Structure of Airtight Container

As shown in FIG. 14, the movable plate part 31 constructing the housing 30 of the airtight container 3 includes the outer rigid part 311 which is formed so that the outer shape thereof is a rectangular frame shape, the inner rigid part 312 formed inside of the outer rigid part 311 having a thickness the same as the outer rigid part 311, and a deformation part 313 which is thinner than the rigid parts 311 and 312 and which is arranged to block a gap 314 having a certain width formed between the outer rigid part 311 and the inner rigid part 312.

Inner edge 311a of the outer rigid part 311 is formed approximately in an oval shape, and outer edge 312a of the inner rigid part 312 is formed approximately in an oval shape while being arranged having a certain gap 314 from the inner edge 311a of the outer rigid part 311. Thin plate 315 having flexibility is joined to the outer surface of the inner rigid part 312 by a joining means such as brazing. This thin plate 315 has a size sufficient to cover over the gap 314 between the rigid parts 311 and 312 and to reach the outer surface of the outer rigid part 311, and the outer edge part thereof is joined to the outer surface of the outer rigid part 311 by a joining means such as brazing. A condition is maintained in which the rigid parts 311 and 312 are connected while existing within the same plane by this thin plate 315. In the present Embodiment, the rigid parts 311 and 312 exist in the same plane; however, the relationship of location of the rigid parts 311 and 312 is not limited to this, and a structure in which they are connected by the thin plate 315 while one of them is shifted to the inside, can be selected.

The part in which the thin plate 315 covers the gap 314 forms the approximately circular deformation part 313 having flexibility, and as shown in FIG. 15, at the central part in the width direction of the deformation part 313, a convex line part 313a protruding to the inside is formed along the entire circumference. The deformation part 313 is arranged so as to extend from the outside of circumference edge surface 312b of the inner rigid part 312 to the outside of inner edge 311a of the outer rigid part 311. The two edges in the Z direction of the outer rigid part 311 are formed so as to unite with end plate part 32. That is, both sides of the outer rigid parts 311 are integrally formed on a pair of upper and lower end plate parts 32, and the inner rigid part 312 is joined to the outer rigid part 311 via the thin plate 315, so as to construct the housing 30. The inner rigid part 312 has a size sufficient to cover over the thermoelectric conversion module 4 and contacts the entire surface of one side of the thermoelectric conversion module 4.

As shown in FIG. 8, multiple outlets for pressure reducing and sealing 321 are arranged on the end plate part 32 of the upper side of the airtight container 3, and pressure in the inner space 3a in the airtight container 3 is reduced by using these outlets for pressure reducing and sealing 321.

### [2-3] Cooling Part and Elastic Plate

The intermediate cooling part 5A and the end part cooling part 5B include a cooling case 53A and 53B, respectively. The cooling case 53A of the intermediate cooling part 5A is formed in a frame shape following the circumference edge of the outer rigid part 311 of the movable plate part 31, is sandwiched between neighboring outer rigid parts 311, and is joined to the outer circumference part of these outer rigid parts 311. That is, in the device of the present invention 1, adjacent housings 30 are in a condition so that adjacent outer rigid parts 311 are mutually joined via the cooling case 53A. A cooling jacket (cooling chamber) 53a which cools the movable plate part 31 by being a pathway for cooling water is formed inside of the intermediate cooling part 5A that is surrounded by the cooling case 53A and the movable plate parts 31 of both sides sandwiching the cooling case 53A.

On the other hand, the cooling case 53B of the end part cooling part 5B is formed in a lid shape covering the movable plate part 31 of the end part, and the edge thereof is joined to the outer circumferential part of the outer rigid part 311, while a shallow concave part formed on one side is oriented to the movable plate part 31 side. The inside of the end part cooling part 5B, which is surrounded by the inner surface of the cooling case 53B and the movable plate part 31, a cooling jacket 53b which cools the movable plate part 31 by being supplied with cooling water, are formed.

A cooling water supply inlet 51 is formed on the lower end surface of the cooling cases 53A and 53B of the intermediate cooling part 5A and the end part cooling part 5B, and a cooling water exhaust outlet 52 is formed on the upper end surface thereof. The cooling water supply inlet 51 and the cooling water exhaust outlet 52 are formed at the center of the X direction, and a cooling water supply tube and an exhaust tube not shown are connected to the cooling water supply inlet 51 and the cooling water exhaust outlet 52, respectively.

In the cooling jackets 53a and 53b of the intermediate cooling part 5A and the end part cooling part 5B, multiple elastic plates 70 which press the inner rigid part 312 of the movable plate part 31 to contact the thermoelectric conversion module 4 and are arranged.

As shown in FIG. 15B, in the end part cooling part 5B, the multiple elastic plates 70 are compressed and sandwiched between the cooling case 53B and the inner rigid part 312. The elastic plate 70 has a fin shape of which the cross section is formed in a corrugated shape, and one end part thereof is joined to the inner surface of the cooling case 53B, and the other end part just contacts the inner rigid part 312 without being joined.

FIG. 15A shows a condition before the cooling case 53B is joined to the outer rigid part 311 of the movable plate part 31, and the other end part of the elastic plate 70 of the inner rigid part 312 side, which is in a free condition, contacts the outer surface of the inner rigid part 312. In this situation, the joined edge of the cooling case 53B to the outer rigid part 311 is separated and faces the outer rigid part 311. The cooling case 53B is moved to the movable plate part 31 side while resisting repulsive force of the elastic plate 70, joined edges thereof are pressed on the outer rigid part 311, and is joined to the outer rigid part 311 while maintaining this condition. In this way, in the case in which the cooling case 53B is assembled against the movable plate part 31, the elastic plate 70 inside of the cooling jacket 53b is sandwiched between the cooling case 53B and the inner rigid part 312 while being elastically compressed.

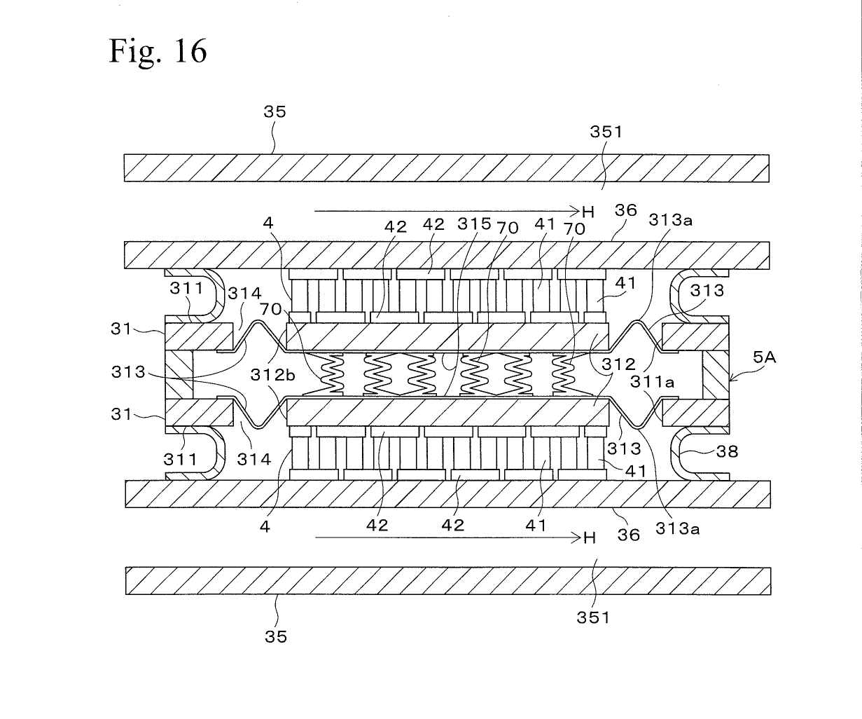

As shown in FIG. 16, one of the end parts of the multiple elastic plates 70 that are arranged in the cooling jacket 53a of the intermediate cooling part 5A are joined to one of the inner rigid part 312, and the other end parts of the multiple elastic plates contact, but are not joined to, the other inner rigid part 312. When the adjacent airtight containers 3 are joined via the cooling case 53A, the elastic plates 70 of the intermediate cooling part 5A are compressed by making adjacent inner rigid parts 312 closer to each other, and then are maintained in a sandwiched condition between the inner rigid parts 312 after joining.

The airtight container 3 is sealed airtight by drawing out the air inside of the inner space 3a of the airtight container 3 from an outlet for pressure reduction and sealing 321 so as to reach a predetermined pressure (about 1 to 100 Pa for example), and by welding the outlet for pressure reducing and sealing 321. In this way, pressure difference occurs in the airtight container 3, that is, the pressure becomes lower than the outer atmosphere, and the movable plate part 31 of the housing 30 receives a force pressed to the inside by this pressure difference.

FIG. 15B shows a condition in which pressure of the inner space 3a inside of the airtight container 3 is reduced, and in the case in which the pressure inside of the inner space 3a is reduced and the movable plate part 31 is pressed to the inside, the deformation part 313 having flexibility deforms so that a convex line part 313a is further protruded to the inside, as shown in the figure. In this way, the inner rigid part 312 contacts the thermoelectric conversion module 4 more strongly in addition to the repulsive force of the elastic plates 70, and is fitted uniformly on the thermoelectric conversion module 4. In other words, the deformation of the deformation part 313 realizes the contacting of the surface of the inner rigid part 312 to the thermoelectric conversion module 4 so as to fit uniformly and strongly to the thermoelectric conversion module 4.

### [2-4] Operation of Generating Device

In the generating device 1 having the above structure, the cooling water is introduced and flows in the cooling jackets 53a and 53b in order to cool the movable plate part 31 of the airtight container 3. On the other hand, the heating fluid H at high temperature flows through each flow tube 35, from one end to the other end, in order to heat the flow tubes 35. Temperature of the movable plate part 31 that is cooled is conducted to an outer surface side of the thermoelectric conversion module 4, and the outer surface side of the thermoelectric conversion module 4 is cooled. On the other hand, the temperature of the inner plate part 36 of the flow tube 35 that is heated is conducted to the inner surface side of the thermoelectric conversion module 4, and the inner surface side of the thermoelectric conversion module 4 is heated. The heating fluid H is not scattered by flowing in the hollow part 351, and the inner plate part 36 of the flow tube 35 is effectively heated.

In this Embodiment, the movable plate part 31 of the housing 30 functions as the tabular member of the cooling side, and the inner plate part 36 of the flow tube 35 functions as the tabular member of the heating side. As described above, by providing a temperature difference between the outer surface side and the inner surface side of the thermoelectric conversion module 4, the thermoelectric conversion module 4 generates electricity, and the electricity can be obtained from the terminals 43.

For example, exhaust heat gas generated in a factory or garbage incinerator or exhaust gas of vehicles is used as the heating fluid H in the generating device 1 of this Embodiment.

### [2-5] Action and Effect of Second Embodiment

By the generating device 1 of the Second Embodiment, the inner rigid part 312 of the movable plate part 31 which is the tabular member of the heating side is pressed due to repulsive force of the elastic plate 70 which is in a compressed condition, and thereby contacts and fits to the thermoelectric conversion module 4. Since the inner rigid part 312 is pressed by the elastic plate 70 and fitted to the thermoelectric conversion module 4 without using a member for fastening such as a tie rod or nut, the inner rigid part 312 can be fitted in uniformly pressed condition on the thermoelectric conversion module 4 without complication and high cost. Furthermore, since the member for fastening such as a bolt and nut is not used, freedom in planning or designing can be improved and the weight can be reduced. Furthermore, stiffness of the inner rigid part 312 can be improved by the elastic plate 70, and the inner rigid part 312 can be prevented from being deformed, and thereby facilitates the inner rigid part 312 to fit the thermoelectric conversion module 4.

Furthermore, the inner rigid part 312 fits to the thermoelectric conversion module 4 in a pressed condition also by an action of reduced pressure in the airtight container 3. The inner rigid part 312 is set to have a thickness not being deformed even if it is pressed to the thermoelectric conversion module 4 side. On the other hand, the deformation part 313 is deformable by conforming movement of the inner rigid part 312 to the inside when pressure in the inner space 3a inside of the airtight container 3 is reduced. Therefore, the condition can be obtained in which the inner rigid part 312 is prevented from being deformed and the inner rigid part 312 reliably contacts the thermoelectric conversion module 4 by a surface and fits uniformly.

Furthermore, as shown in FIG. 16, the elastic plate 70 that is contained in the cooling jacket 53a of the intermediate cooling part 5A is arranged sandwiched between each inner rigid part 312 of the adjacent airtight container 3. On the other hand, as shown in FIG. 15B, the elastic plate 70 which is contained in the cooling jacket 53b of the end part cooling part 5B generates repulsive force by pressing the cooling case 53B to the housing 30 side, fixing thereon, and holding, thereby giving the repulsive force of the elastic plate 70 reliably to the thermoelectric conversion module 4.

Furthermore, the elastic plate 70 is joined at one end part to the cooling case 53B in the case of the end part cooling part 5B, and to one of the inner rigid parts 312 of both sides sandwiching in the case of the intermediate cooling part 5A. The other end part of the elastic plate is contacted to the other side in a condition not joined. In this way, handling and assembling of the elastic plate 70 become easy. In addition, since the not-joined-side of the elastic plate 70 can move relatively to the thermoelectric conversion module 4 or the inner rigid part 312 even in the case in which the thermoelectric conversion module 4 or the inner rigid part 312 expands or contracts by heating and cooling, therefore, only slight disadvantages of deformation due to stress by the influence of heat occur.

In addition, since pressure of the inner space 3a in the airtight container 3 is reduced, the inner space 3a is difficult to heat compared to a case in which the inner space 3a contains gas such as air at normal pressure. Therefore, disadvantages can be reduced in which the airtight container 3 is adversely affected by expansion of inner gas or the thermoelectric conversion module 4 is deteriorated by heating. The deformation part 313 can be easily arranged since the deformation part 313 of the movable plate part 31 is thinner than the inner rigid part 312 and deformable.

Furthermore, in this Embodiment, the cooling water that flows in the cooling jackets 53a and 53b contacts the elastic plate 70. Since the heat of the inner rigid part 312 is conducted to the elastic plate 70 and the elastic plate 70 is cooled by the cooling water, radiation of heat can be performed by the elastic plate 70. Therefore, it is desirable that the elastic plate 70 be formed in a fin shape like in this Embodiment, since cooling effect is improved.

### [2-6] Variation of Second Embodiment

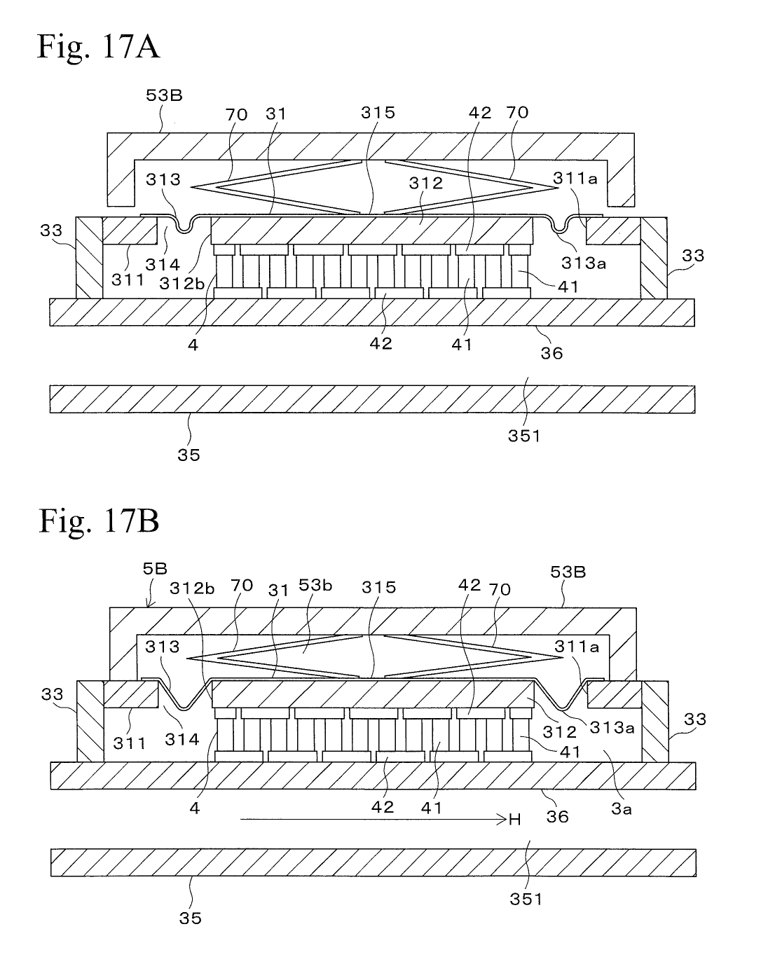

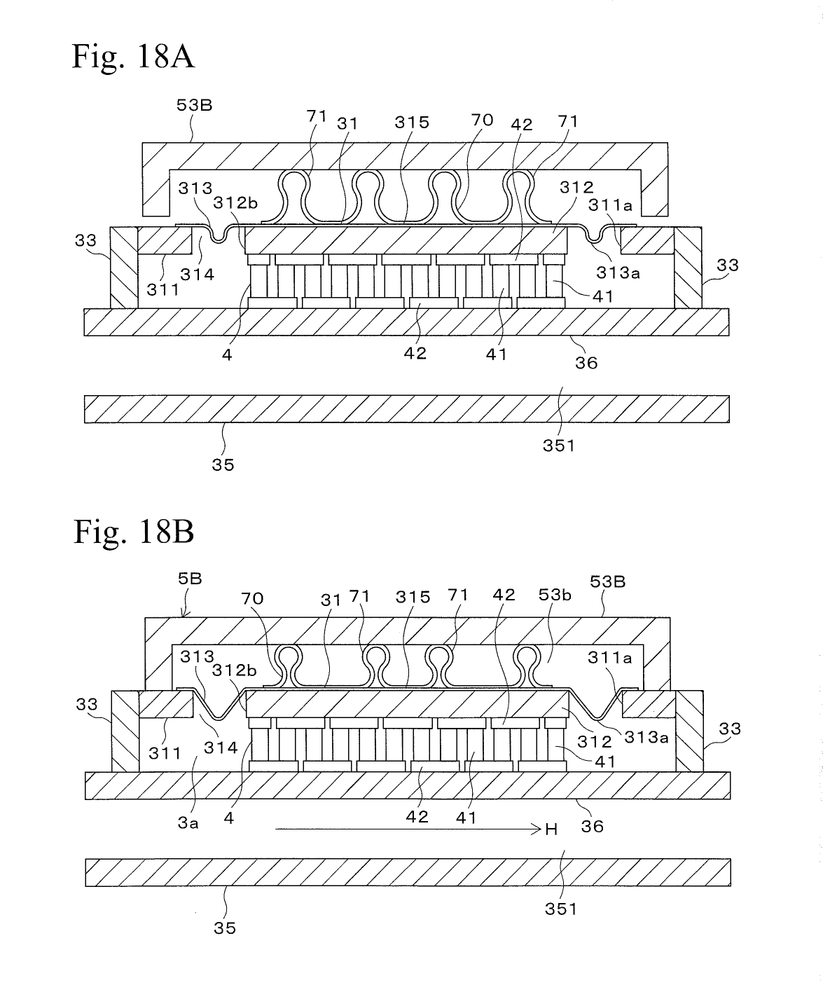

The elastic plate 70 is not limited to the shape in the above Embodiment as long as it presses the inner rigid part 312 toward the thermoelectric conversion module 4. For example, a pair of the elastic plates 70 each having a V-shaped cross section arranged in a horizontally symmetric condition as shown in FIG. 17, or the elastic plate 70 in which the convex line parts 71 having an Q shaped cross section, are arranged in parallel, as shown in FIG. 18, may be mentioned. These figures of A show a condition before the cooling case 53B of the end part cooling part 5B is joined to the outer rigid part 311 of the movable plate part 31, and these figures of B show a condition in which the cooling case 53B is joined to the outer rigid part 311, and therefore the inner rigid part 312 of the movable plate part 31 is pressed to the thermoelectric conversion module 4 by the elastic plate 70. As the elastic plate 70, the fin shape mentioned above is desirable since it contacts the cooling water and thereby yields the heat radiation effect.

In addition, a buffer material consisting of a flexible material can be arranged, for example, between the thermoelectric conversion module 4 and at least one of the tabular member of the cooling side (the inner rigid part 312 of the movable plate part 31 in the airtight container 3) and the tabular member of the heating side (the inner plate part 36 of the flow tube 35 in the airtight container 3). In such cases, the airtight container 3 contacts the thermoelectric conversion module 4 via the buffer material in a pressed condition and thereby protects the thermoelectric conversion module 4 by the buffer material.

Next, the Third and Fourth Embodiments, having basically the same overall structure, are explained. In the following, in explanation about these Embodiments, the same or similar reference numeral is given to a constitutional element similar to that in the Second Embodiment referred to in the figure, and explanation thereof is omitted.

### [3] Third Embodiment

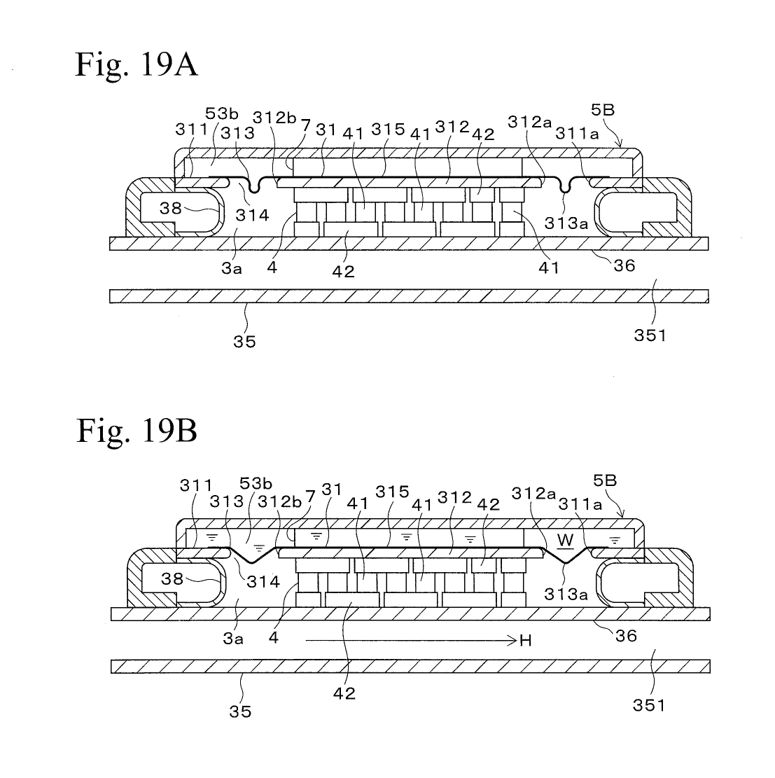

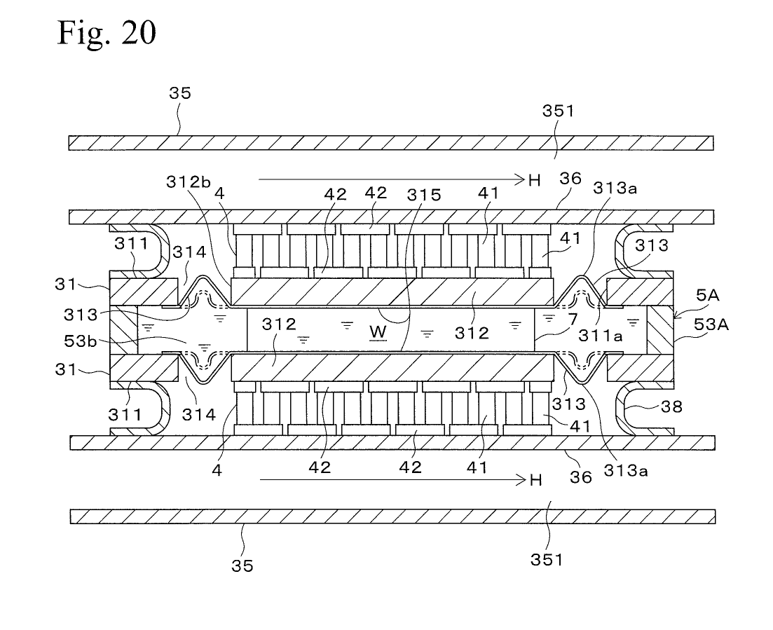

The Third Embodiment of the present invention is explained with reference to FIGS. 19 and 20.

The Third Embodiment is characterized by the inner pressure being generated in the cooling jackets 53a and 53b by the cooling water (fluid for cooling) that is supplied in the cooling jackets 53a and 53b in the Second Embodiment. The action is explained as follows.

FIG. 19A shows a condition before pressure inside of the end airtight container 3 in which the end part cooling part 5B is arranged is reduced. As shown in FIG. 19B, in a case in which the movable plate part 31 is pressed to the inside by reducing pressure, a convex line part 313a of the deformation part 313 having flexibility is deformed further protruding to the inside, and whereby the inner rigid part 312 contacts the thermoelectric conversion module 4. In other words, the deformation of the deformation part 313 realizes the contact surface of the inner rigid part 312 moving to the thermoelectric conversion module 4 so as to fit to the thermoelectric conversion module 4.

Furthermore, FIG. 20 shows a condition in which pressure of the airtight container 3 of both sides of the intermediate cooling part 5A is reduced. A convex line part 313a of the deformation part 313 having flexibility is similarly deformed protruding to the inside, and thereby the inner rigid part 312 contacts the thermoelectric conversion module 4. (two-dot chain line of the deformation part 313 indicates a condition before reducing pressure)

In this Embodiment, as shown in FIGS. 19B and 20, the movable plate part 31 of the airtight container 3 is cooled by supplying and flowing the cooling water Win each of cooling jackets 53a and 53b. On the other hand, the heating fluid H (for example, exhaust heat gas generated in a factory or garbage incinerator or exhaust gas of vehicles) at high temperature flows through each flow tube 35, from one end to the other end in order to heat the flow tubes 35. In this way, in a manner similar to that of the Second Embodiment, a temperature difference is produced between the outer surface side and inner surface side of the thermoelectric conversion module 4, whereby the thermoelectric conversion module 4 generates electricity, and the electricity can be obtained from the terminals 43.

In this Embodiment, the cooling water W is always supplied in the cooling jackets 53a and 53b of the each of the cooling parts 5A and 5B in an amount sufficient to generate inner pressure in the cooling jackets 53a and 53b to a certain extent (for example, 0.1 to 1 MPa). In this way, by generating the inner pressure (pressure in the positive direction) in the cooling jackets 53a and 53b by the cooling water W, the inner rigid part 312 of the movable plate part 31 contacts the thermoelectric conversion module 4 in a pressed condition by the inner pressure. As a result, the inner rigid part 312 can be fitted to the thermoelectric conversion module 4 in a uniformly pressed condition. In this way, heat conductivity from the cooling parts 5A and 5B to the thermoelectric conversion module 4 via the inner rigid part 312 of the movable plate part 31 is improved, temperature difference imparted to the thermoelectric conversion module 4 is increased, and power generation efficiency is improved.

Furthermore, since the inner rigid part 312 is pressed by using the cooling water Win the cooling jackets 53a and 53b and is contacted to the thermoelectric conversion module 4, the inner rigid part 312 can be fitted to the thermoelectric conversion module 4 in a uniformly pressed condition without complicating the device and increasing cost. Furthermore, since a fastening member such as a bolt or nut is not used, freedom in planning or designing can be improved and the weight can be reduced.

Furthermore, in this Embodiment, the movable plate part 31 which is the tabular member of the cooling side consists of the inner rigid part 312 for contacting to the thermoelectric conversion module 4 and the deformation part 313 having flexibility arranged therearound. Therefore, the condition can be obtained in which the deformation part 313 is deformed and the inner rigid part 312 contacted to the thermoelectric conversion module 4 reliably and uniformly. Furthermore, by making the rigid part as a part fitting to the thermoelectric conversion module 4, the parts reliably contacts the thermoelectric conversion module 4 via a surface without being deformed, and a uniformly pressed condition to the thermoelectric conversion module 4 is easily obtained.

In addition, in this Embodiment, the inner rigid part 312 of the movable plate part 31 contacts the thermoelectric conversion module 4 in a pressed condition also by reducing pressure inside of the airtight container 3 in addition to the inner pressure in the cooling jackets 53a and 53b. Therefore, fitting property of the inner rigid part 312 on the thermoelectric conversion module 4 can be further improved. In addition, since pressure inside of the airtight container 3 is reduced, inside of the airtight container 3 is difficult to be heated compared to a case in which the airtight container 3 contains gas such as air at normal pressure. Therefore, disadvantages can be reduced in which the airtight container 3 is adversely affected by expansion of inner gas or the thermoelectric conversion module 4 is deteriorated by heating.

### [4] Fourth Embodiment

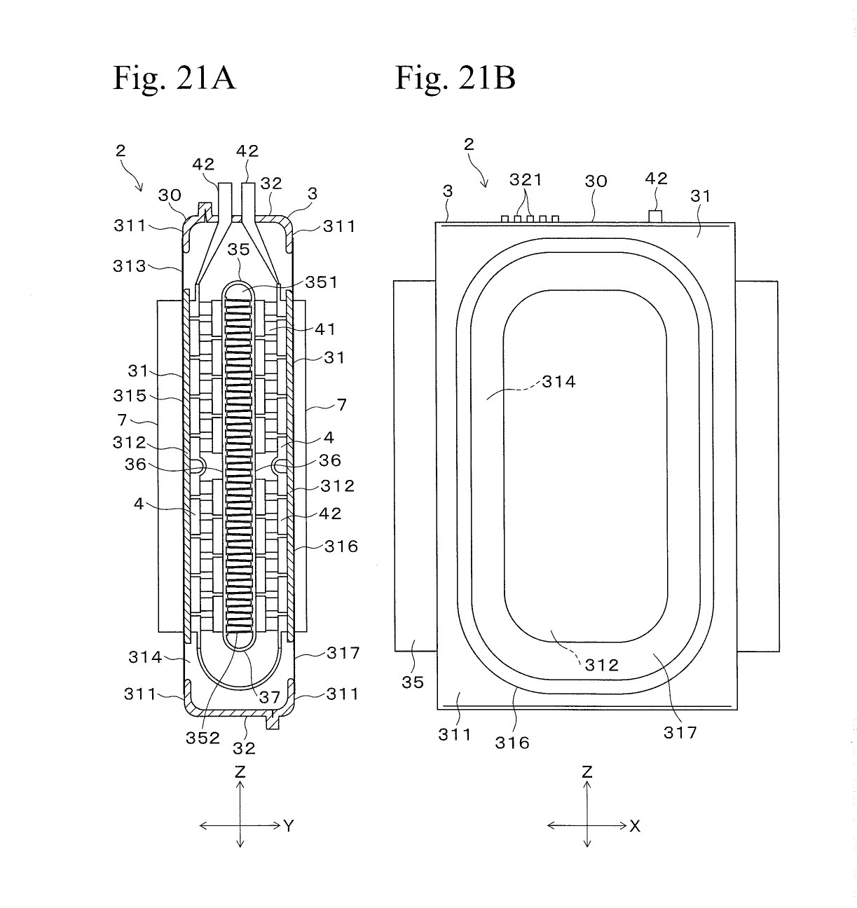

Next, the Fourth Embodiment of the present invention is explained with reference to FIGS. 21 to 23.

The Fourth Embodiment has an elastic part 317 arranged instead of the deformation part 313, in the airtight container 3 of the Second and Third Embodiments. An airtight container 3 of the Fourth Embodiment is explained as follows.

### [4-1] Structure of Airtight Container

As shown in FIG. 21, a movable plate part 31 which constructs a housing 30 of the airtight container 3 of the Fourth Embodiment includes an outer rigid part 311 that is formed to have a rectangular frame shape as an outer shape; an inner rigid part 312 which has the same thickness as that of the outer rigid part 311 and which is arranged inside of the outer rigid part 311; and the elastic part 317 which is thinner than the rigid parts 311 and 312 and which is arranged so as to seal a gap 314 which is a gap of a certain width and is formed between the outer rigid part 311 and the inner rigid part 312.

Inner edge 311a of the outer rigid part 311 is formed approximately in an oval shape, and outer edge 312a of the inner rigid part 312 is formed approximately in an oval shape and is arranged having the certain gap 314 from the inner edge 311a of the outer rigid part 311. On the outer surface of the inner rigid part 312, a spring plate 316 having elasticity is joined by a joining means such as brazing. This spring plate 316 has an size sufficient to cover the gap 314 between the rigid parts 311 and 312 and to reach the outer surface of the outer rigid part 311, and outer edge part thereof is joined to the outer surface of the outer rigid part 311 by a joining means such as brazing.

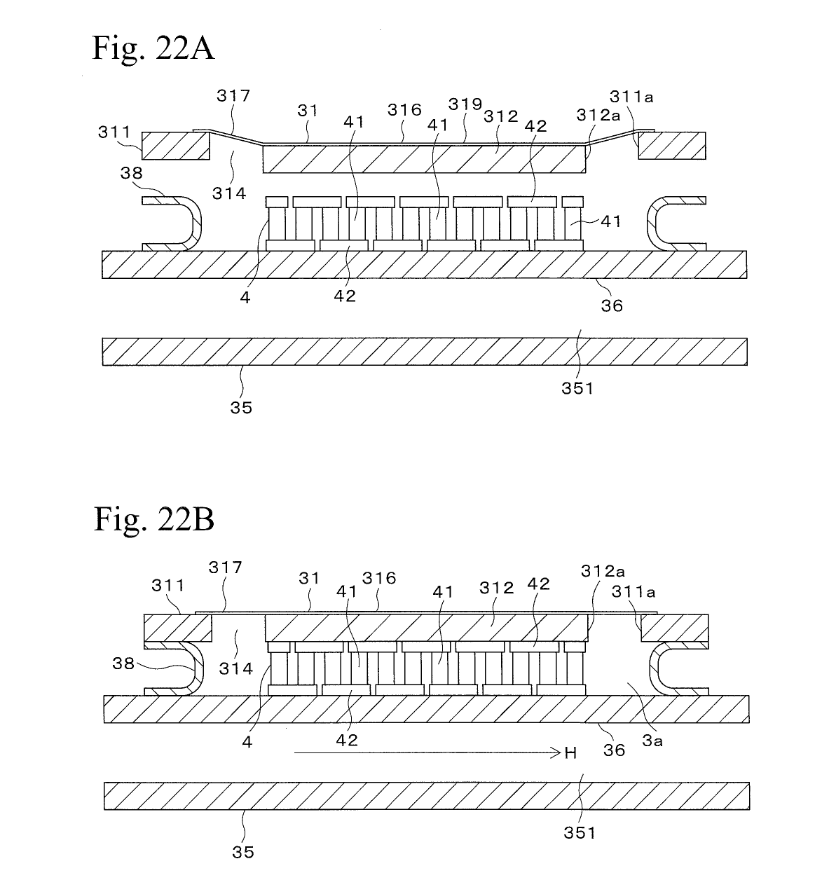

The region of the spring plate 316 that covers over the gap 314 forms the elastic part 317 having approximately a circular shape. This elastic part 317 is arranged in a condition existing from the outside of the outer edge 312a of the inner rigid part 312 to the outside of the inner edge 311a of the outer rigid part 311, and in a free condition before assembling as the airtight container 3 having the thermoelectric conversion module 4 inside, as shown in FIG. 22A, it inclines to the inside. That is, the spring plate 316 is bent to the inside at the outer edge 311a of the outer rigid part 311, extends straight, and is again bent at the outer edge 312a of the inner rigid part 312 so as to be joined to an outer surface of the inner rigid part 312. Therefore, the entirety of the movable plate part 31 of the housing 30 is in a condition in which concave region 319 is formed from the elastic part 317 to the inner rigid part 312 in a free condition of the elastic part 317.

Multiple outlets for pressure reducing and sealing 321 are arranged at an end plate part 32 upward of the airtight container 3, and pressure of the inner space 3a inside of the airtight container 3 is reduced via these outlets for pressure reducing and sealing 321.

Both ends in the Z direction of the outer rigid part 311 are formed in a condition in which they are unified with the end plate part 32. That is, the outer rigid parts 311 of both sides are integrally formed with the upper and lower pair of the end plates part 32, and the inner rigid part 312 is joined to the outer rigid part 311 via the spring plate 316, so as to construct the housing 30. The inner rigid part 312 has a size covering over the thermoelectric conversion module 4, and is in a condition contacting the entire surface of one side of the thermoelectric conversion module 4.

In the airtight container 3 having the above structure, when assembling by joining the inner surface of the outer rigid part 311 of the movable plate part 31 to the sealing cover 38 in a condition in which the thermoelectric conversion module 4 is arranged inside, as shown in FIG. 22B, the inner surface of the inner rigid part 312 of the movable plate part 31 contacts the thermoelectric conversion module 4, the elastic part 317 is elastically deformed to the outside, the concave region 319 disappears, the outer rigid part 311 and the inner rigid part 312 become in almost the same plane, and the elastic part 317 becomes almost parallel to the rigid parts 311 and 312. In this assembled condition, the inner rigid part 312 is strongly contacted to the thermoelectric conversion module 4 and fits uniformly to the thermoelectric conversion module 4, by repulsive force of the elastic part 317 that is deformed. It should be noted that the rigid parts 311 and 312 exist in almost the same plane in this Embodiment; however, the relationship of position of the rigid parts 311 and 312 is not limited to this, and a structure in which one of them is aligned to the inside and they are connected by the spring plate 316, can be selected.

Next, the airtight container 3 is sealed airtight by drawing out the air inside from an outlet for pressure reducing and sealing 321 so as to reach a predetermined pressure (about 1 to 100 Pa for example), and by welding the outlet for pressure reducing and sealing 321.

Structure and power generating action of each cooling part (intermediate cooling part 5A and end part cooling part 5B) are the same as in the Second and Third Embodiments.

### [4-2] Action and Effect of Airtight Container

In this Embodiment, the inner rigid part 312 of the movable plate part 31 of the airtight container 3 contacts the thermoelectric conversion module 4 in a pressed condition by repulsive force of the elastic part 317 of the spring plate 316, and fits uniformly. Thus, heat conductivity from the cooling parts 5A and 5B to the thermoelectric conversion module 4 via the inner rigid part 312 is improved, the temperature difference given to the thermoelectric conversion module 4 increases, and power generation efficiency is improved.

Since the inner rigid part 312 which is the tabular member of the cooling side fits to the thermoelectric conversion module 4 by repulsive force of the elastic part 317 of the movable plate part 31 without using a member for fastening such as a tie rod or nut, unlike in a conventional technique, the inner rigid part 312 can be fitted in uniformly pressed condition on the thermoelectric conversion module 4 without complication and high cost. Furthermore, since the member for fastening, such as a bolt and nut, is not used, freedom in planning or designing can be improved and the weight can be reduced.

The inner rigid part 312 which fits to the thermoelectric conversion module 4 in a pressed condition by elasticity of the elastic part 317 of the movable plate part 31, is set to have a thickness so that it will not deform even if pressed to the thermoelectric conversion module 4 side. Therefore, the inner rigid part 312 is prevented from being deformed, and the inner rigid part 312 can reliably contacted to the thermoelectric conversion module 4 by a surface and can fit uniformly.

In addition, since pressure in the airtight container 3 is reduced, the inside of the airtight container 3 is difficult to heat compared to a case in which the airtight container contains gas, such as air, at normal pressure. Therefore, disadvantages can be reduced in which the airtight container 3 is adversely affected by expansion of inner gas or the thermoelectric conversion module 4 is deteriorated by heating.

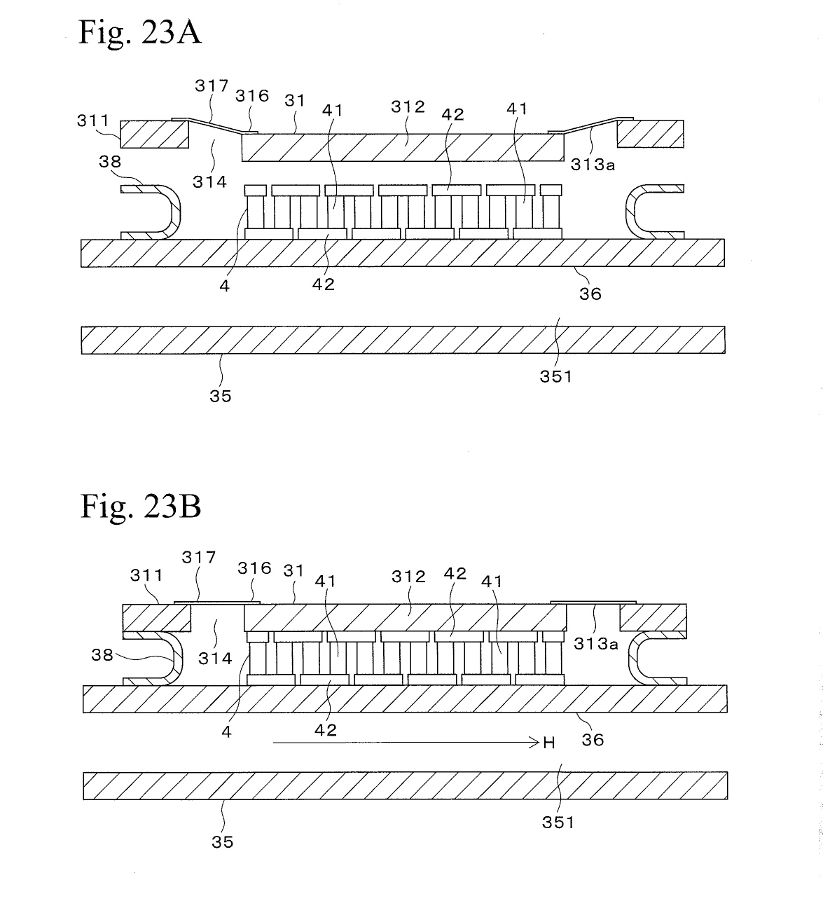

In the present Embodiment, various variations are possible. For example, as shown in FIG. 23, the spring plate 316 which forms the elastic part 317 can be formed to be circular having a certain extent of width to cover the gap 314 between the outer rigid part 311 and the inner rigid part 312, instead of one which covers the entirety of the outer surface of the inner rigid part 312.

What is claimed is:

1. A thermoelectric conversion generating device comprising:
an airtight container in which a tabular member of a heating side and a tabular member of a cooling side are arranged facing each other, and in which pressure inside thereof is reduced, and
a thermoelectric conversion module contained in the airtight container in a condition that the module is arranged between the tabular member of the heating side and the tabular member of the cooling side,
wherein the thermoelectric conversion module generates electricity by producing a temperature difference in the thermoelectric conversion module by heating the tabular member of the heating side and cooling the tabular member of the cooling side at the same time,
the tabular member of the cooling side consists of a flexible tabular member that is flexible, and
the flexible tabular member contacts the thermoelectric conversion module directly or via a buffer material in a condition in which the flexible tabular member is pressed by a pressure difference inside and outside of the airtight container that occurs due to a condition of reduced pressure in the airtight container.

2. The thermoelectric conversion generating device according to claim 1, wherein a deformation part that deforms by the pressure difference is formed around the thermoelectric conversion module in the flexible tabular member.

3. The thermoelectric conversion generating device according to claim 1, wherein a heat exchanging means for improving cooling is arranged on the tabular member of the cooling side, in a condition in which flexibility of the tabular member of the cooling side can be maintained.

4. The thermoelectric conversion generating device according to claim 3, wherein the heat exchanging means comprises a heat exchanging member that is flexible.

5. The thermoelectric conversion generating device according to claim 3, wherein the heat exchanging means comprises isolated multiple heat exchanging members, which are arranged while being scattered and contacted to the tabular member of the cooling side of the flexible tabular member.

6. The thermoelectric conversion generating device according to claim 1, wherein a hollow part is formed by the tabular member of the heating side, the thermoelectric conversion module is arranged around the hollow part, and the tabular member of the cooling side is arranged outside of the thermoelectric conversion module, and
wherein a heating fluid flows through the hollow part so as to heat the tabular member of heating side.

7. The thermoelectric conversion generating device according to claim 1, wherein a cooling fluid is supplied and the cooling fluid contacts the tabular member of the cooling side, and
the device further comprises a cooling chamber in which pressure therein can be increased by the cooling fluid.
